(19) United States
(12) Patent Application Publication
(10) Pub. No.: US 2026/0114304 A1
(43) Pub. Date: Apr. 23, 2026

(54) PACKAGE STRUCTURE AND METHOD OF FABRICATING THE SAME

(71) Applicant: Taiwan Semiconductor Manufacturing Company, Ltd., Hsinchu (TW)

(72) Inventors: Guan-Yu Chen, Hsinchu City (TW); Chun-Wei Chen, New Taipei City (TW); Wan-Yu Lee, Taipei City (TW); An-Jhih Su, Taoyuan City (TW); Hua-Wei Tseng, New Taipei City (TW); Ta-Hsuan Lin, Hsinchu City (TW)

(73) Assignee: Taiwan Semiconductor Manufacturing Company, Ltd., Hsinchu (TW)

(21) Appl. No.: 18/922,418

(22) Filed: Oct. 22, 2024

(51) Int. Cl. H01L 23/498; H01L 21/48; H01L 21/56; H01L 21/683; H01L 23/00; H01L 25/16; H10B 80/00

(52) U.S. Cl. CPC H10W 70/65; H10P 72/74; H10W 70/05; H10W 70/093; H10W 74/01; H10W 90/701; H10B 80/00; H10W 74/10; H10W 74/15; H10W 90/00; H10W 90/401; H10W 90/726; H10W 90/736; H10W 90/754

(57) ABSTRACT

A package structure includes a redistribution layer, a plurality of semiconductor dies and a bonding layer. The redistribution layer has a first surface and a second surface opposite to the first surface, and includes a plurality of conductive lines and a plurality of conductive vias connected to the plurality of conductive lines. Seed layers are located below the conductive lines and the conductive vias, wherein a portion of the seed layers is revealed at the second surface. The semiconductor dies are disposed on the first surface of the redistribution layer and electrically connected to the redistribution layer. The bonding layer is disposed on the second surface of the redistribution layer, wherein the bonding layer comprises a plurality of bonding pads, and a bottom surface of the plurality of bonding pads is joined to the portion of the seed layers revealed at the second surface.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 are schematic sectional and bottom views of various stages in a method of fabricating a semiconductor package according to some exemplary embodiments of the disclosure.

FIG. 10 is a schematic sectional view of a package structure according to some exemplary embodiments of the disclosure.

FIG. 11 is a schematic sectional view of a package structure according to some other exemplary embodiments of the disclosure.

FIG. 12 is a schematic sectional view of a package structure according to some other exemplary embodiments of the disclosure.

FIG. 13 is a schematic sectional view of a semiconductor package according to some other exemplary embodiments of the disclosure.

FIG. 14 is a schematic sectional view of a semiconductor package according to some other exemplary embodiments of the disclosure.

FIG. 15 is a schematic sectional view of a semiconductor package according to some other exemplary embodiments of the disclosure.

FIG. 16 to FIG. 18 are schematic sectional views of various stages in a method of fabricating a package structure according to some comparative embodiments of the disclosure.

FIG. 19A is an enlarged sectional view of the package structure obtained in FIG. 18 according to some comparative embodiments of the disclosure.

FIG. 19B is an enlarged sectional view of the package structure obtained in FIG. 10 according to some exemplary embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Package structures such as chip-on-wafer (CoW) structures are generally formed by bonding chips or dies on a wafer substrate having a redistribution layer, and subsequently forming under bump metallurgies (UBM) patterns on the redistribution layer (RDL), and forming conductive terminals on the UBM patterns. Due to the presence of seed layers when forming the redistribution layer and forming the UBM patterns, a crack observed in the underfill during a board level reliability test may extend and propagate along the side of the seed layers, causing a crack to be also observed in the dielectrics of the redistribution layer. The crack observed in the dielectrics will usually cause delamination, resulting in an opening path that allows for humidity penetration, resulting in the formation of RDL dendrite overtime. The delamination and formation of RDL dendrite will cause electrical failure and cause reliability issues. In accordance with some embodiments of the present disclosure, a package structure is formed so that the delamination issue and the formation of the RDL dendrite is prevented.

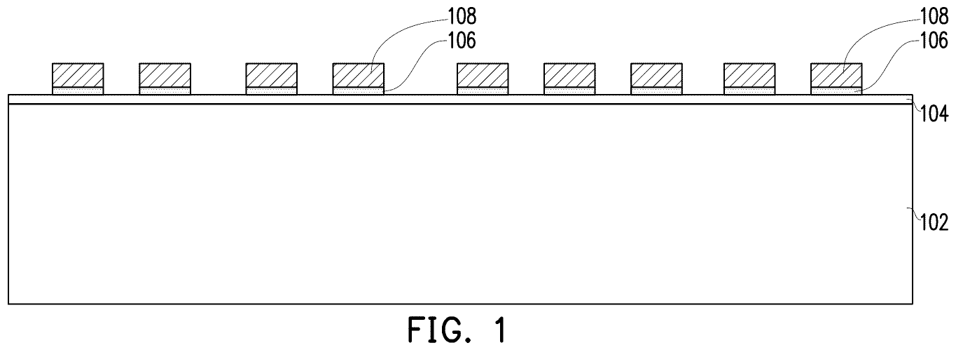

FIG. 1 to FIG. 9 are schematic sectional and bottom views of various stages in a method of fabricating a semiconductor package according to some exemplary embodiments of the disclosure. Referring to FIG. 1, a carrier 102 is provided. In some embodiments, the carrier 102 may be a glass carrier or any suitable carrier for carrying a semiconductor wafer or a reconstituted wafer for the manufacturing method of the package structure. In some embodiments, the carrier 102 is coated with a debond layer 104. The material of the debond layer 104 may be any material suitable for bonding and de-bonding the carrier 102 from the above layer(s) or any wafer(s) disposed thereon.

In some embodiments, the debond layer 104 may include a dielectric material layer made of a dielectric material including any suitable polymer-based dielectric material (such as benzocyclobutene (“BCB”), polybenzoxazole (“PBO”)). In an alternative embodiment, the debond layer 104 may include a dielectric material layer made of an epoxy-based thermal-release material, which loses its adhesive property when heated, such as a light-to-heat-conversion (LTHC) release coating film. In a further alternative embodiment, the debond layer 104 may include a dielectric material layer made of an ultra-violet (UV) glue, which loses its adhesive property when exposed to UV lights. In certain embodiments, the debond layer 104 may be dispensed as a liquid and cured, or may be a laminate film laminated onto the carrier 102, or may be the like. The top surface of the debond layer 104, which is opposite to a bottom surface contacting the carrier 102, may be levelled and may have a high degree of coplanarity. In certain embodiments, the debond layer 104 is, for example, a LTHC layer with good chemical resistance, and such layer enables room temperature de-bonding from the carrier 102 by applying laser irradiation, however the disclosure is not limited thereto.

In an alternative embodiment, a buffer layer (not shown) may be coated on the debond layer 104, where the debond layer 104 is sandwiched between the buffer layer and the carrier 102, and the top surface of the buffer layer may further provide a high degree of coplanarity. In some embodiments, the buffer layer may be a dielectric material layer. In some embodiments, the buffer layer may be a polymer layer which made of polyimide, PBO, BCB, or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

As further illustrated in FIG. 1, seed layer 106 is formed on the debond layer 104. In some embodiments, a photoresist (not shown) is formed on the seed layer 106, and have openings revealing portions of the seed layer 106. Subsequently, a plurality of bonding pads 108 are formed in the openings of the photoresist. In some embodiments, the bonding pads 108 are formed by performing an electroplating process.

In some embodiments, the seed layer 106 is a metal layer, which may be a single layer or a composite layer including a plurality of sub-layers formed of different materials. In some embodiments, the seed layer 106 includes a titanium layer and a copper layer over the titanium layer. In certain embodiments, the seed layer 106 is a titanium layer formed by a sputtering process. In some embodiments, the bonding pads 108 are plated in the openings of the photoresist by using the seed layer 106 as a seed. The bonding pads 108 may be metal pads or under bump metallurgies (UBM) patterns. In some embodiments, the bonding pads 108 include Cu, Ti, Ta, W, Ru, Co, Ni. Au or an alloy thereof. In certain embodiments, the bonding pads 108 include Cu. After forming the bonding pads 108, the photoresist is removed, and portions of the seed layer 106 is removed by using the bonding pads 108 as a mask. As such, the remaining portions of the seed layers 106 (sacrificial seed layers) are located below each of the bonding pads 108. For example, sidewalls (or edge) of the seed layers 106 are aligned with sidewalls (or edge) of the bonding pads 108.

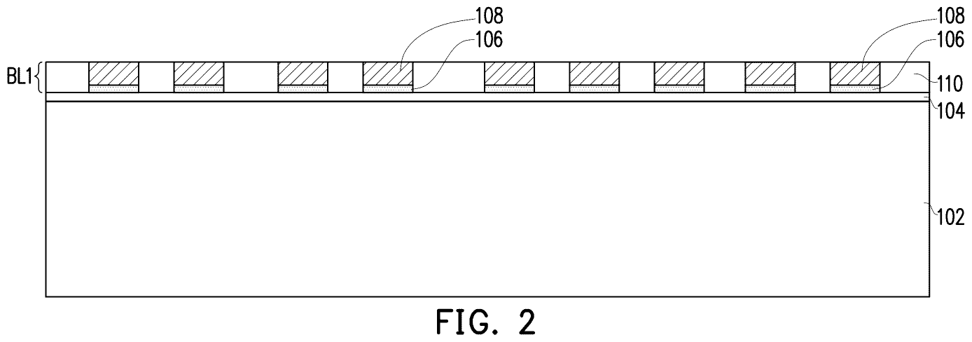

Referring to FIG. 2, after forming the bonding pads 108, a dielectric portion 110 is formed to surround the bonding pads 108 and the seed layers 106. For example, the dielectric portion is covering sidewalls of the bonding pads 108, and covering sidewalls of the seed layers 106. In some embodiments, the dielectric portion 110 is a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like. In certain embodiments, a planarization process is performed on the dielectric portion 110 so that a top surface of the dielectric portion 110 is substantially aligned with a top surface of the bonding pads 108. For example, the planarization process includes a chemical mechanical polishing (CMP) process, a mechanical grinding step, or the like. In some embodiments, after the mechanical grinding or chemical mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods. In some embodiments, the seed layers 106, the bonding pads 108 and the dielectric portion 110 together constitutes a bonding layer BL1.

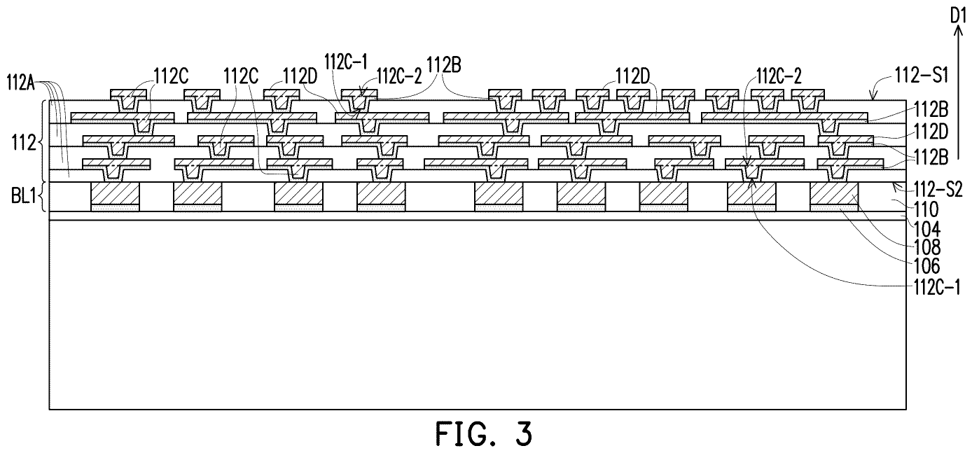

Referring to FIG. 3, in a subsequent step, a redistribution layer 112 is formed on the bonding layer BL1. In some embodiments, forming the redistribution layer 112 includes forming a plurality of dielectric layers 112A, a plurality of seed layers 112B, a plurality of conductive vias 112C and a plurality of conductive lines 112D alternately stacked along a first direction D1. The number of layers of the dielectric layers 112A, the number of layers of the seed layers 112B, the number of layers of the conductive vias 112C and conductive lines 112D are not particularly limited, and may be adjusted based on product requirement. In some embodiments, the seed layers 112B are electrically connected to the bonding pads 108 located underneath. In certain embodiments, the bonding pads 108 are physically separated from the conductive lines 112D and the conductive vias 112C of the redistribution layer 112.

In some embodiments, the material of the dielectric layers 112A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 112A are formed by suitable fabrication techniques such as spin-on coating, chemical vapor deposition (CVD), plasma-enhanced chemical vapor deposition (PECVD) or the like. The disclosure is not limited thereto.

In some embodiments, the material of the seed layers 112B include titanium, or the like. The seed layers 112B may be formed using, for example, PVD, or the like. In some embodiments, the material of the conductive vias 112C and the conductive lines 112D may be made of conductive materials formed by electroplating or deposition, such as aluminum, titanium, copper, nickel, tungsten, and/or alloys thereof, which may be patterned using a photolithography and etching process. In some embodiments, the conductive vias 112C and the conductive lines 112D may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In the exemplary embodiment, the redistribution layer 112 includes a first surface 112-S1 and a second surface 112-S2 opposite to the first surface 112-S1. For example, the seed layers 112B revealed at the second surface 112-S2 are attached to the bonding pads 108 of the bonding layer BL1, while the first surface 112-S1 of the redistribution layer 112 is facing away from the bonding layer BL1. In other words, the bonding layer BL1 is located on the first surface 112-S1 of the redistribution layer 112, and is electrically connected to seed layers 112B of the redistribution layer 112 through the bonding pads 108. In some embodiments, the conductive lines 112D are disposed on and electrically connected to conductive vias 112C. Furthermore, the seed layers 112B are located below the conductive lines 112D and the conductive vias 112C.

As further illustrated in FIG. 3, each of the conductive vias 112C comprises a first side 112C-1 and a second side 112C-2 opposite to the first side 112C-1. For example, the first side 112C-1 is joined with the seed layers 112B, while the second side 112C-2 is joined with the conductive lines 112D. In some embodiments, a lateral dimension of each of the conductive vias 112C increases from the first side 112C-1 to the second side 112C-2 along the first direction D1. Furthermore, the bonding pads 108 are disposed and attached on the seed layers 112B that are located over the first side 112C-1 of the conductive vias 112C.

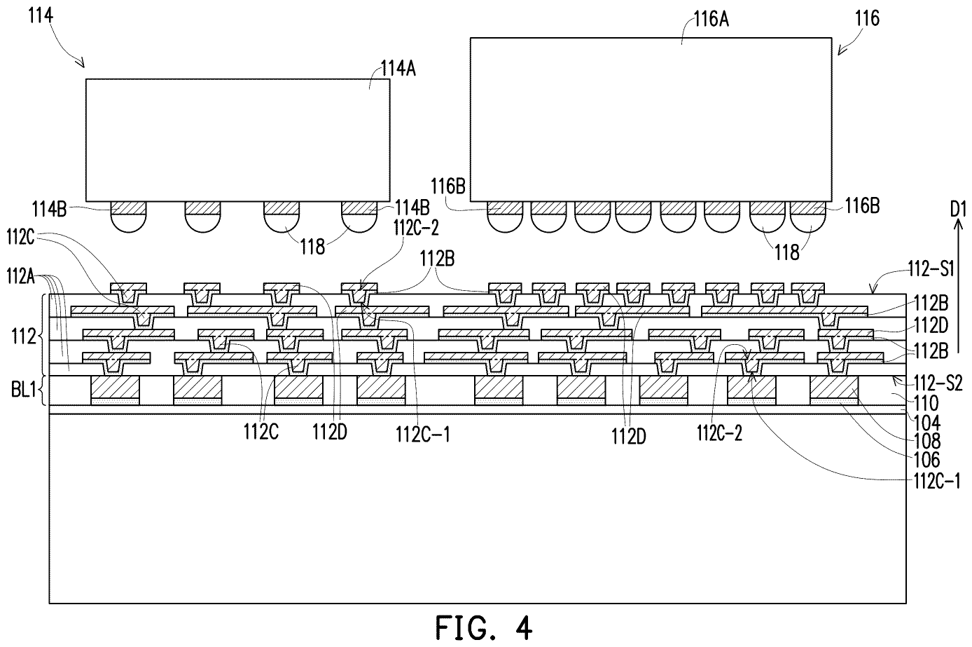

Referring to FIG. 4, after forming the redistribution layer 112, a first semiconductor die 114 and a second semiconductor die 116 are provided over the redistribution layer 112 for bonding. Although only two semiconductor dies are illustrated herein, it is noted that there may in fact be more than two dies provided for bonding to the redistribution layer 112. In the exemplary embodiment, the first semiconductor die 114 and the second semiconductor die 112 are individual dies singulated from a wafer. The backsides of the first semiconductor die 114 may be grinded or partially removed so that is has a reduced thickness relative to the thickness of the second semiconductor die 116.

In some embodiments, the first semiconductor die 114 and the second semiconductor die 116 have different circuitry or are different types of dies. In some embodiments, from a top view of the first and second semiconductor dies 114, 116 (not shown), the second semiconductor die 116 have a surface area larger than that of the first semiconductor die 114, but the disclosure is not limited thereto. In some embodiments, the first semiconductor die 114 may be a memory die, including dynamic random access memory (DRAM) die, static random access memory (SRAM) die or a high bandwidth memory (HBM) die. In some embodiments, the second semiconductor die 116 may be a logic die, including a central processing unit (CPU) die, graphics processing unit (GPU) die, system-on-a-chip (SoC) die, a microcontroller or the like.

As further illustrated in FIG. 4, the first semiconductor die 114 include a body 114A and connecting pads 114B formed on an active surface of the body 114A. In certain embodiments, the connecting pads 114B may further include conductive bumps 118 for bonding the first semiconductor die 114 to other structures. Similarly, in some embodiments, the second semiconductor die 116 include a body 116A and connecting pads 116B formed on an active surface of the body 116A. In other embodiments, the connecting pads 116B may further include conductive bumps 118 for bonding the second semiconductor dies 116 to other structures. In some embodiments, the conductive bumps 118 are micro-bumps, such as micro-bumps having copper metal pillars. In another embodiment, the conductive bumps 118 are solder bumps, lead-free solder bumps, or micro bumps, such as controlled collapse chip connection (C4) bumps or micro bumps containing copper pillars.

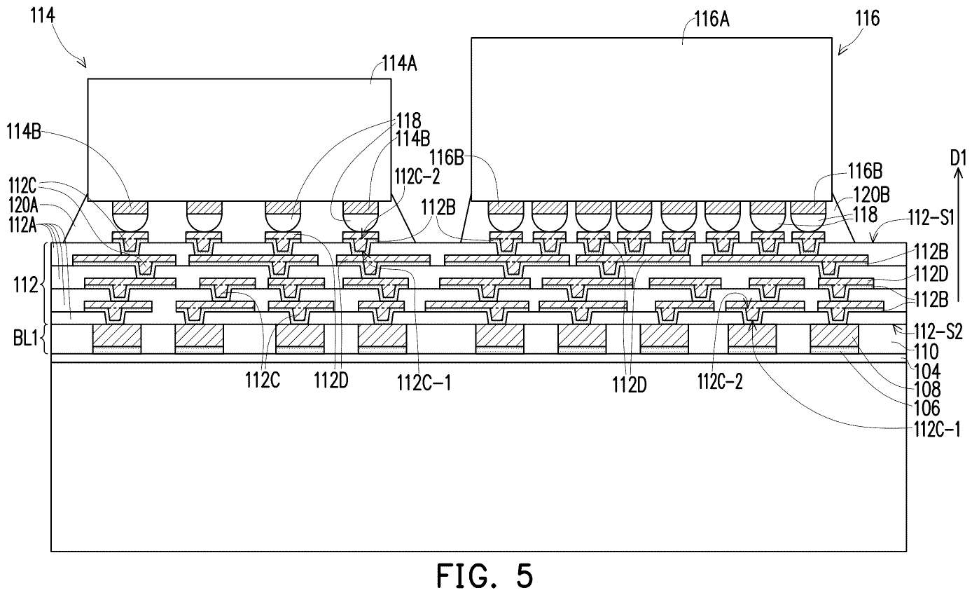

Referring to FIG. 5, in some embodiments the first semiconductor die 114 and the second semiconductor die 116 are attached to the redistribution layer 112, for example, through flip-chip bonding by way of the conductive bumps 118. Through a reflow process, the conductive bumps 118 are arranged between the connecting pads 114B, the connecting pads 116B and the conductive lines 112D of the redistribution layer 112, and are electrically and physically connecting the first and second semiconductor dies 114, 116 to the redistribution layer 112.

In a subsequent step, an underfill structure 120A is formed between the first semiconductor die 114 and the redistribution layer 112 to cover and laterally surround the connecting pads 114B, the conductive bumps 118 and the conductive lines 112D. Similarly, an underfill structure 120B is formed between the second semiconductor die 116 and the redistribution layer 112 to cover and laterally surround the connecting pads 116B, the conductive bumps 118 and the conductive lines 112D. In some embodiments, the underfill structure 120A is partially covering sidewalls of the first semiconductor die 114, while the underfill structure 120B is partially covering sidewalls of the second semiconductor die 116. Furthermore, in some embodiments, the underfill structure 120A is physically separated from the underfill structure 120B.

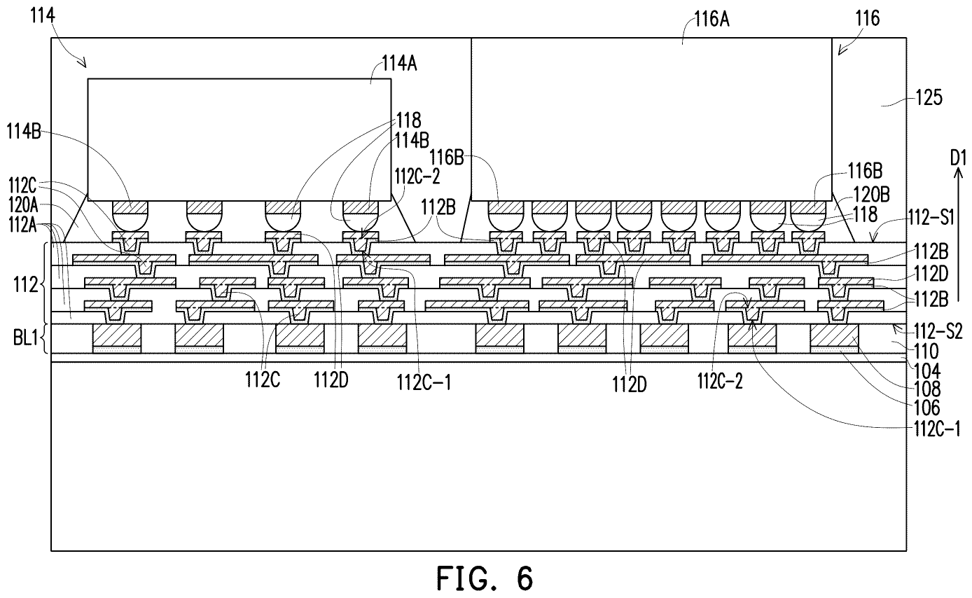

Referring to FIG. 6, in some embodiments, an insulating encapsulant 125 (or molding compound) may be formed over the redistribution layer 112 to cover the conductive bumps 118, the underfill structures 120A, 120, and to surround the first and second semiconductor dies 114, 116. In some embodiments, the insulating encapsulant 125 is formed through, for example, a compression molding process or transfer molding. In one embodiment, a curing process is performed to cure the insulating encapsulant 125. In some embodiments, a planarization or grinding process is performed on the insulating encapsulant 125. For example, after the planarization or grinding process, a backside surface of the second semiconductor die 116 is revealed by the insulating encapsulant 125, while a backside surface of the first semiconductor die 114 is covered by the insulating encapsulant 125.

In some embodiments, a material of the insulating encapsulant 125 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 125 may include an acceptable insulating encapsulation material. In some embodiments, the insulating encapsulant 125 may further include inorganic filler or inorganic compound (e.g. silica, clay, and so on) which can be added therein to optimize coefficient of thermal expansion (CTE) of the insulating encapsulant 125. The disclosure is not limited thereto.

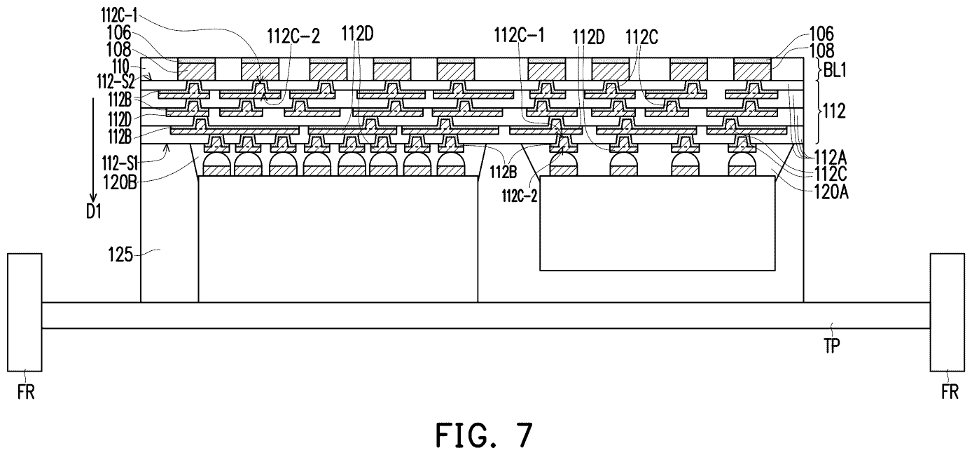

Referring to FIG. 7, in a subsequent step, the structure shown in FIG. 6 is flipped and placed on a tape TP supported by a frame FR. Thereafter, the carrier 102 is de-bonded, and is separated from the bonding layer BL1. For example, the de-bonding process includes projecting a light such as a laser light or an UV light on the debond layer 104 (e.g., the LTHC release layer) so that the carrier 102 can be easily removed along with the debond layer 104. After removing the carrier 102 and the debond layer 104, the seed layers 106 (sacrificial seed layers) of the bonding layer BL1 are revealed.

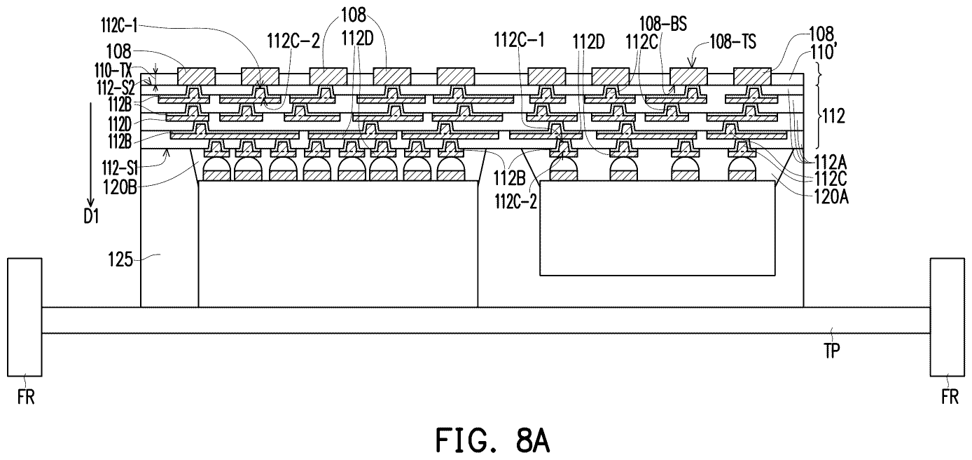

Referring to FIG. 8A, after the de-bonding process, a recessing step is performed to remove the seed layers 106 (sacrificial seed layers), and for partially removing the dielectric portion 110 to form a recessed dielectric portion 110′. For example, the recessing step includes a dry etching step that removes the seed layers 106 for revealing a surface of the bonding pads 108. In the exemplary embodiment, after the recessing step, the bonding pads 108 are formed with a seed-free bottom surface 108-BS and a seed-free top surface 108-TS. For example, the seed-free bottom surface 108-BS of the bonding pads 108 is directly joined with the seed layers 112B of the redistribution layer 112. As illustrated in FIG. 8B, from a bottom view of one of the bonding pads 108, it can be seen that a surface area A1 of the seed-free bottom surface 108-BS contacting the seed layer 112B of the redistribution layer 112 is less than a surface area A2 of the seed-free bottom surface 108-BS of the bonding pads 108 contacting the dielectric layer 112A of the redistribution layer 112.

Referring back to FIG. 8A, in some embodiments, after the recessing step, a thickness 110-TX of the dielectric portion 110′ (recessed dielectric portion) is smaller than a thickness of the bonding pads 108. In other words, the bonding pads 108 may be protruding over a top surface of the dielectric portion 110′, or the dielectric portion 110′ is recessed from the seed-free top surface 108-TS of the bonding pads 108. In certain embodiments, the thickness 110-TX of the dielectric portion 110′ is greater than half of the thickness of the bonding pads 108. In other words, the dielectric portion 110′ is slightly recessed from the seed-free top surface 108-TS of the bonding pads 108. In some embodiments, the dielectric portion 110′ is partially covering sidewalls of the bonding pads 108. In some embodiments, a bottom surface of the dielectric portion 110′ is aligned with the seed-free bottom surface 108-BS of the bonding pads 108.

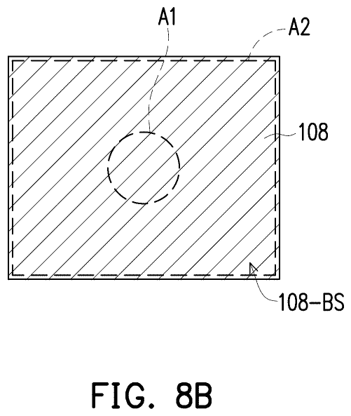

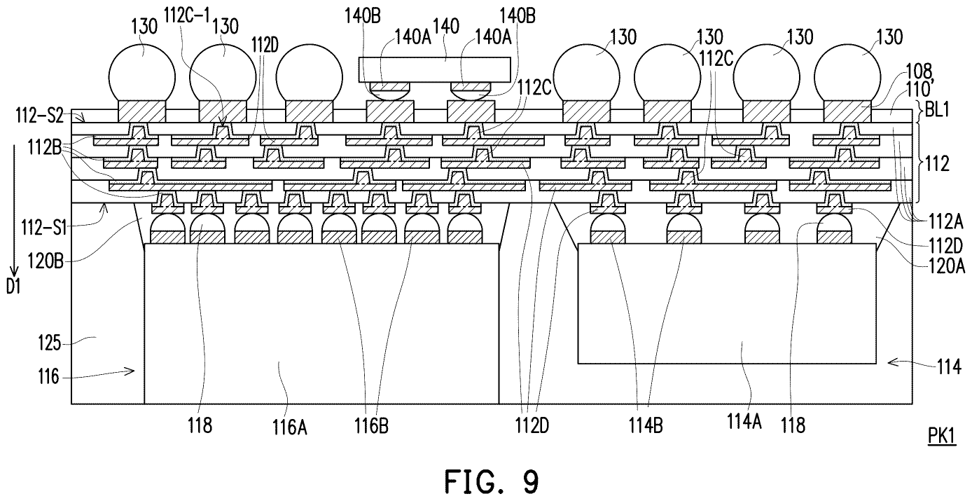

Referring to FIG. 9, in a subsequent step, a plurality of conductive terminals 130 is directly formed on the seed-free top surface 108-TS of the bonding pads 108, and a passive device 140 is directly disposed on the seed-free top surface 108-TS of the bonding pads 108. In some embodiments, the conductive terminals 130 include lead-free solder balls, solder balls, ball grid array (BGA) balls, bumps, C4 bumps or micro bumps. In some embodiments, the conductive terminals 130 may include a conductive material such as solder, copper, aluminum, gold, nickel, silver, palladium, tin, or a combination thereof. In some embodiments, the conductive terminals 130 are formed by forming the solder paste on the bonding pads 108 by, for example, evaporation, electroplating, printing or solder transfer and then reflowed into the desired bump shapes. In some embodiments, the conductive terminals 130 are placed on the conductive pads 130 by ball placement or the like. In other embodiments, the conductive terminals 130 are formed by forming solder-free metal pillars (such as a copper pillar) by sputtering, printing, electroless or electro plating or CVD, and then forming a lead-free cap layer by plating on the metal pillars. The conductive terminals 130 may be used to bond to an external device or an additional electrical component. In some embodiments, the conductive terminals 130 are used to bond to a circuit substrate, a semiconductor substrate or a packaging substrate.

In some embodiments, the passive device 140 includes conductive pads 140A disposed on a substrate, and includes conductive bumps 140B disposed on the conductive pads 140B. In some embodiments, the conductive bumps 140B of the passive device 140 is physically and electrically connected to the seed-free top surface 108-TS of the bonding pads 108 through a soldering process. After forming the conductive terminals 130 and placing the passive device 140 on the bonding pads 108 of the bonding layer BL1, a semiconductor package PK1 in accordance with some embodiments of the present disclosure is accomplished.

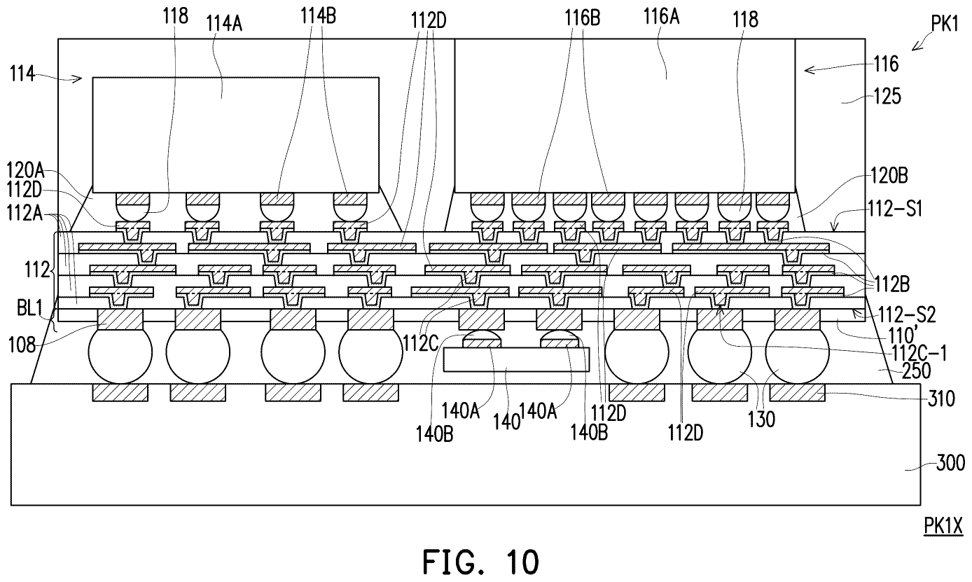

FIG. 10 is a schematic sectional view of a package structure according to some exemplary embodiments of the disclosure. As illustrated in FIG. 10, the semiconductor package PK1 obtained in FIG. 9 is mounted or attached onto a circuit substrate 300 through the conductive terminals 130. In some embodiments, the circuit substrate 300 is such as an organic flexible substrate or a printed circuit board. In some embodiments, the circuit substrate 300 includes contact pads 310, wherein the semiconductor package PK1 is bonded to the circuit substrate 300 by joining the conductive terminals 130 to the contact pads 310.

Referring to FIG. 10, in a subsequent step, an underfill structure 250 is formed to fill up the spaces in between the circuit substrate 300 and the semiconductor package PK1. In some embodiments, the underfill structure 250 fills up the spaces in between adjacent conductive terminals 130 and covers the conductive terminals 130. For example, the underfill structure 250 laterally surrounds the plurality of conductive terminals 130. In some embodiments, the underfill structure 250 further covers the passive device 140 and covers the bonding layer BL1. For example, the underfill structure 250 is physically contacting the conductive terminals 130 and the bonding pads 108, and is surrounding and contacting the dielectric portion 110′. After forming the underfill structure 250, a package structure PK1X in accordance with some embodiments of the present disclosure is accomplished.

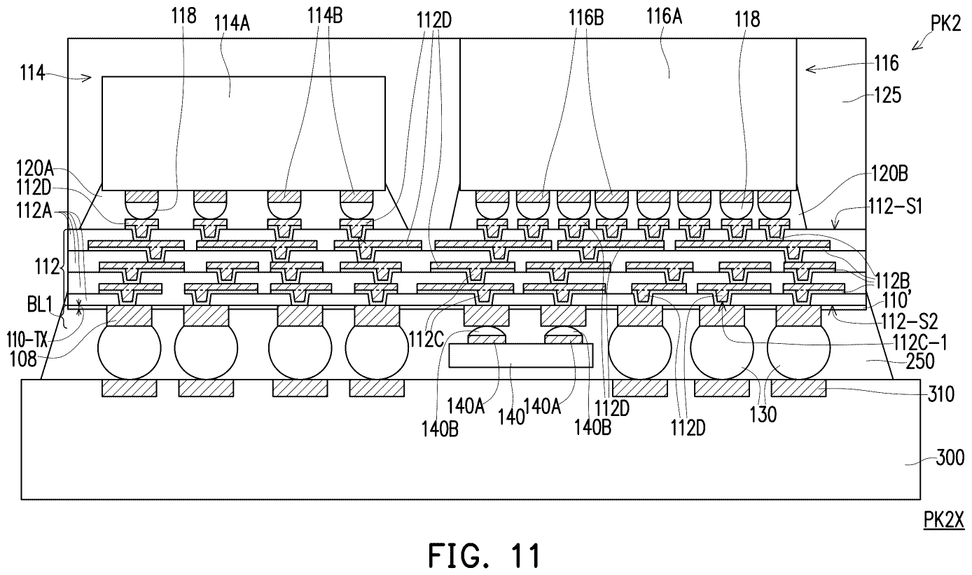

FIG. 11 is a schematic sectional view of a package structure according to some other exemplary embodiments of the disclosure. The package structure PK2X shown in FIG. 11 is similar to the package structure PK1X shown in FIG. 10. Therefore, the same reference numerals are used to refer to the same or liked parts, and its detailed description will not be repeated herein. The difference between the embodiments is that the semiconductor package PK1 is replaced with a semiconductor package PK2 in FIG. 11.

As shown in FIG. 11, in the semiconductor package PK2, the bonding layer BL1 is formed so that the dielectric portion 110′ (recessed dielectric portion) is smaller than a thickness of the bonding pads 108. For example, the thickness 110-TX of the dielectric portion 110′ is less than half of the thickness of the bonding pads 108. In other words, a majority of the dielectric portion 110′ is recessed from the seed-free top surface 108-TS of the bonding pads 108. The semiconductor package PK2 may bonded to the circuit substrate 300 in a similar way to the semiconductor package PK1 as described in FIG. 10. Thereafter, an underfill structure 250 may be formed to fill up the spaces in between the circuit substrate 300 and the semiconductor package PK2 to obtain the package structure PK2X.

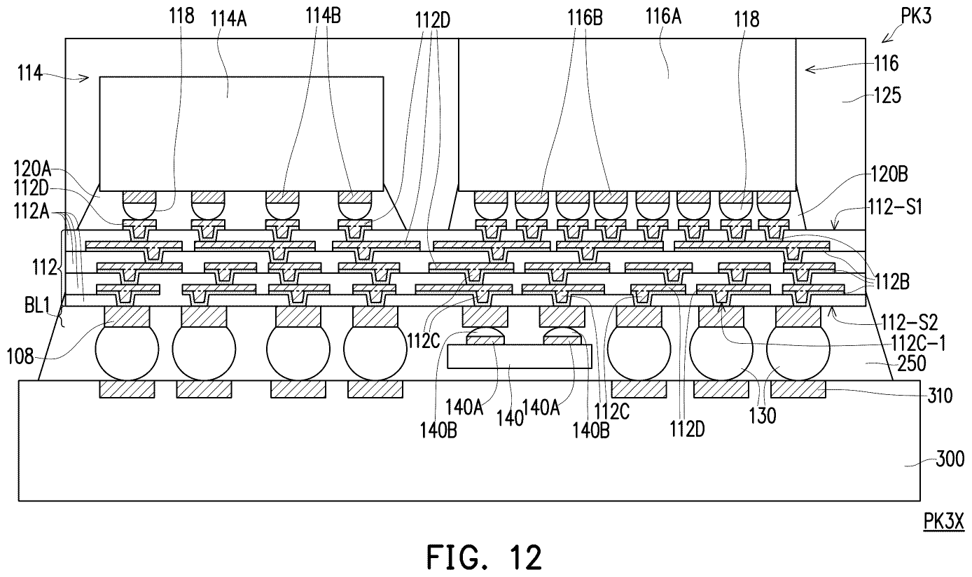

FIG. 12 is a schematic sectional view of a package structure according to some other exemplary embodiments of the disclosure. The package structure PK3X shown in FIG. 12 is similar to the package structure PK1X shown in FIG. 10. Therefore, the same reference numerals are used to refer to the same or liked parts, and its detailed description will not be repeated herein. The difference between the embodiments is that the semiconductor package PK1 is replaced with a semiconductor package PK3 in FIG. 12.

As shown in FIG. 12, in the semiconductor package PK3, the bonding layer BL1 is formed so that the dielectric portion 110′ is removed during the recessing step, and the dielectric layer 112A of the redistribution layer 112 is revealed. The semiconductor package PK3 may bonded to the circuit substrate 300 in a similar way to the semiconductor package PK1 as described in FIG. 10. Thereafter, an underfill structure 250 may be formed to fill up the spaces in between the circuit substrate 300 and the semiconductor package PK3 to obtain the package structure PK3X. In the package structure PK3X, the underfill structure 250 entirely covers the sidewalls of the bonding pads 108.

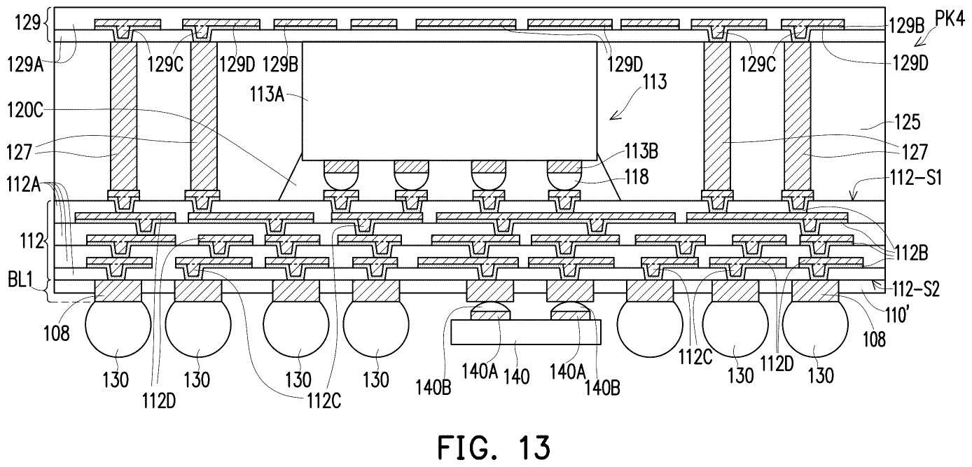

FIG. 13 is a schematic sectional view of a semiconductor package according to some other exemplary embodiments of the disclosure. The semiconductor package PK4 illustrated in FIG. 13 is similar to the semiconductor package PK1 illustrated in FIG. 9. Therefore, the same reference numerals are used to refer to the same and liked parts, and its detailed description will not be repeated herein.

As illustrated in FIG. 13, the bonding layer BL1 and the redistribution layer 112 is formed in a similar way to the bonding layer BL1 and the redistribution layer 112 shown in FIG. 9. For example, the bonding layer BL1 of FIG. 13 includes a dielectric portion 110′ that is recessed from the seed-free top surface 108-TS of the bonding pads 108. Furthermore, the seed-free bottom surface 108-BS of the bonding pads 108 is directly joined to the seed layer 112B of the redistribution layer 112.

Referring to FIG. 13, in some embodiments, a semiconductor die 113 is bonded to the redistribution layer 112. In some embodiments, the semiconductor die 113 include a body 113A and connecting pads 113B formed on an active surface of the body 113A. In certain embodiments, the connecting pads 113B may further include conductive bumps 118 for bonding the semiconductor die 113 to other structures. In some embodiments, the semiconductor die 113 is attached to the redistribution layer 112, for example, through flip-chip bonding by way of the conductive bumps 118. Through a reflow process, the conductive bumps 118 are arranged between the connecting pads 113B and the conductive lines 112D of the redistribution layer 112, and are electrically and physically connecting the semiconductor die 113 to the redistribution layer 112.

After bonding the semiconductor die 113 to the redistribution layer 112, an underfill structure 120C is formed between the semiconductor die 113 and the redistribution layer 112 to cover and laterally surround the connecting pads 113B, the conductive bumps 118 and the conductive lines 112D. Furthermore, in some embodiments, a plurality of through insulator vias 127 is formed to surround the semiconductor die 113, and formed to be electrically connected to the redistribution layer 112.

In some embodiments, the through insulator vias 127 are through integrated fan-out (“InFO”) vias. In one embodiment, the formation of the through insulator vias 127 includes forming a mask pattern (not shown) with openings, then forming a metallic material (not shown) filling up the openings by electroplating or deposition, and removing the mask pattern to form the through insulator vias 127 on the redistribution layer 112. In certain embodiments, the through insulator vias 127 is formed to be electrically connected to the conducive lines 112D of the redistribution layer 112. In some embodiments, the material of the mask pattern may include a positive photo-resist or a negative photo-resist. In one embodiment, the material of the through insulator vias 127 may include a metal material such as copper or copper alloys, or the like. However, the disclosure is not limited thereto.

After forming the underfill structure 120C and the through insulator vias 127, an insulating encapsulant 125 is formed on the redistribution layer 112 to encapsulate the semiconductor die 113, the underfill structure 120C and the through insulator vias 127. Thereafter, a redistribution layer 129 is formed on the insulating encapsulant 125 to be electrically connected to the through insulator vias 127. In the exemplary embodiment, forming the redistribution layer 129 includes forming a plurality of dielectric layers 129A, a plurality of seed layers 129B, a plurality of conductive vias 129C and a plurality of conductive lines 129D alternately stacked. The materials and method of forming the dielectric layers 129A, the seed layers 129B, the conductive vias 129C and the conductive lines 129D are similar to the materials and method of forming the dielectric layers 112A, the seed layers 112B, the conductive vias 112C and the conductive lines 112D. Therefore, the details will not be repeated herein.

In the exemplary embodiment, a recessing step of the bonding layer BL1 is preformed after forming the redistribution layer 129 so as to remove any seed layer located on the bonding pads 108, and to form the dielectric portion 110′ that is recessed from the seed-free top surface 108-TS of the bonding pads 108. After forming the conductive terminals 130 and after placing the passive device 140 on the seed-free top surface 108-TS of the bonding pads 108, the semiconductor package PK4 is accomplished.

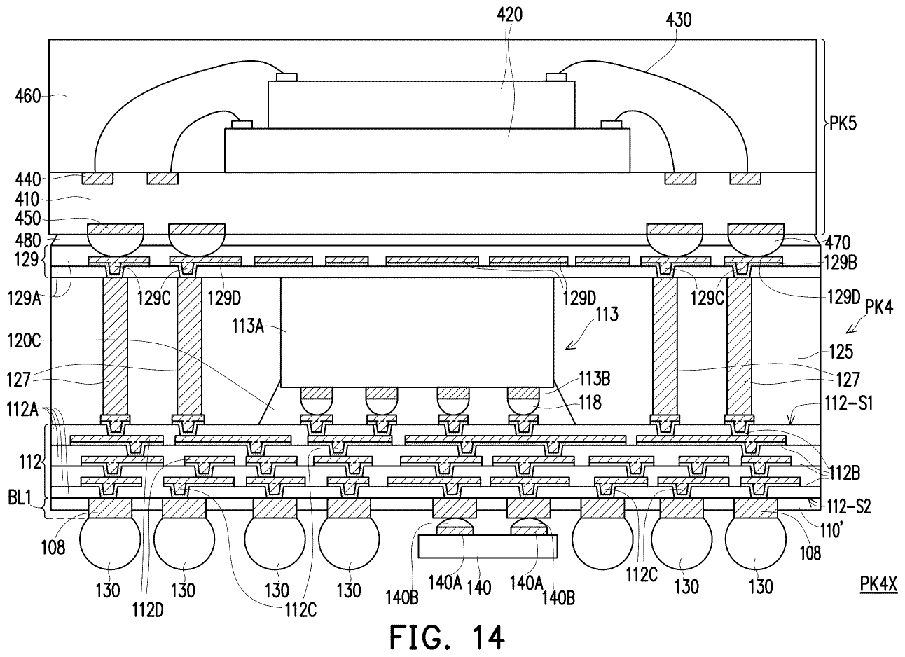

FIG. 14 is a schematic sectional view of a semiconductor package according to some other exemplary embodiments of the disclosure. In some embodiments, after forming the semiconductor package PK4 illustrated in FIG. 13, another package PK5 may be stacked on the semiconductor package PK4 to form a package-on-package (PoP) structure PK4X. As illustrated in FIG. 14, the package PK5 is electrically connected to the conductive lines 129D of the semiconductor package PK4.

In some embodiments, the package PK5 has a substrate 410, a plurality of semiconductor chips 420 mounted on one surface (e.g. top surface) of the substrate 410 and stacked on top of one another. In some embodiments, bonding wires 430 are used to provide electrical connections between the semiconductor chips 420 and pads 440 (such as bonding pads). In some embodiments, an insulating encapsulant 460 is formed to encapsulate the semiconductor chips 420 and the bonding wires 4530 to protect these components. In some embodiments, through insulator vias (not shown) may be used to provide electrical connection between the pads 440 and conductive pads 450 (such as bonding pads) that are located on another surface (e.g. bottom surface) of the substrate 410. In certain embodiments, the conductive pads 450 are electrically connected to the semiconductor chips 420 through these through insulator vias (not shown). In some embodiments, the conductive pads 450 of the package PK5 are electrically connected to conductive balls 470. Furthermore, the conductive balls 470 are electrically connected to the conductive lines 129D of the redistribution layer 129 in the semiconductor package PK4. In some embodiments, an underfill 480 is further provided to fill in the spaces between the conductive balls 470 to protect the conductive balls 470. After stacking the package PK5 on the semiconductor package PK4 and providing electrical connection therebetween, a package-on-package structure PK4X can be fabricated.

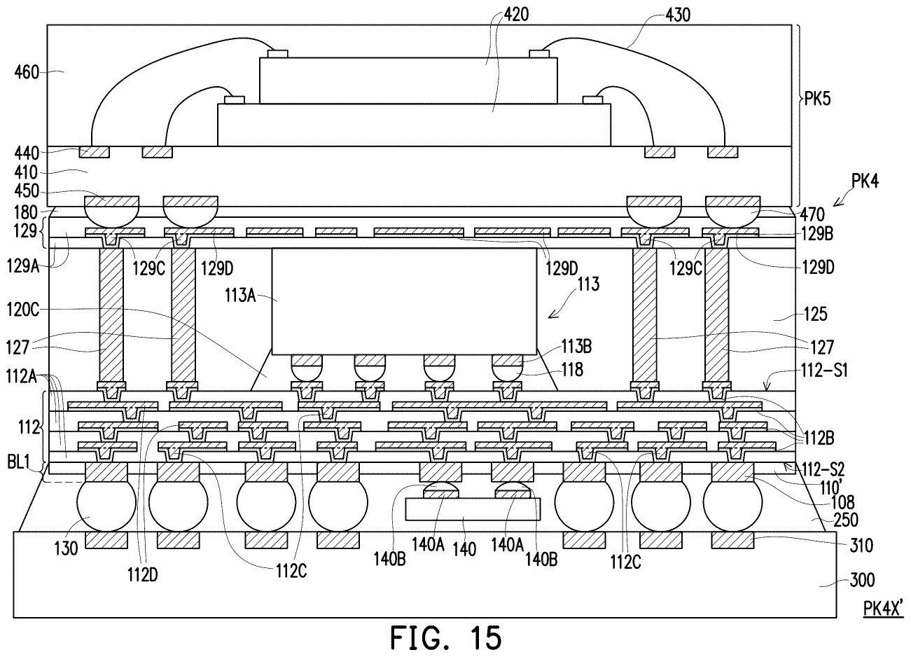

FIG. 15 is a schematic sectional view of a semiconductor package according to some other exemplary embodiments of the disclosure. Referring to FIG. 15, in some embodiments, the PoP structure PK4X illustrated in FIG. 14 is mounted or attached onto a circuit substrate 300 through the conductive terminals 130. For example, the conductive terminals 130 of the PoP structure PK4X are electrically connected to the contact pads 310 of the circuit substrate 300. In a subsequent step, an underfill structure 250 is formed to fill up the spaces in between the circuit substrate 300 and the PoP structure PK4X. After forming the underfill structure 250, a package structure PK4X′ in accordance with some embodiments of the present disclosure is accomplished.

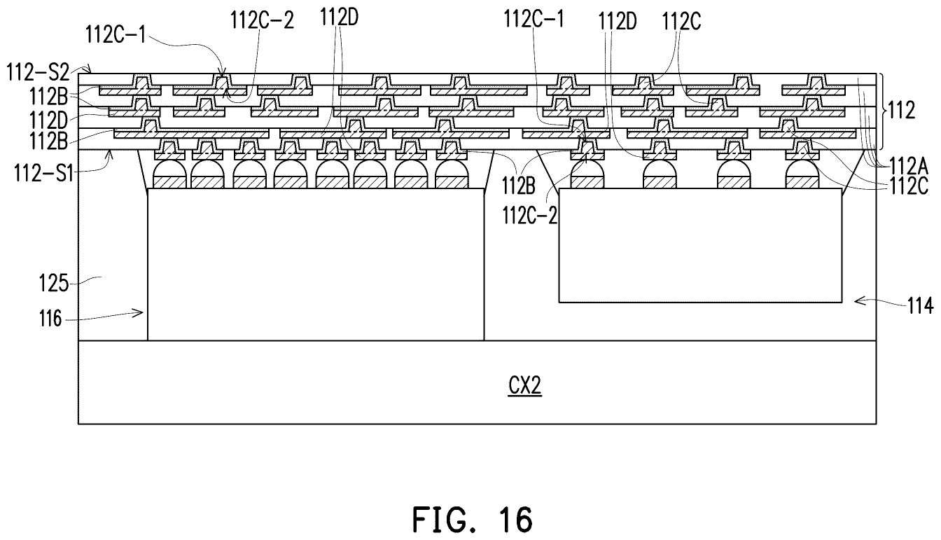

FIG. 16 to FIG. 18 are schematic sectional views of various stages in a method of fabricating a package structure according to some comparative embodiments of the disclosure. In the previous embodiments, the seed layers 106 and the bonding pads 108 of the bonding layer BL1 are formed prior to forming the redistribution layer 112. As such, a recessing step can be performed to remove the seed layers 106 and to form the bonding pads 108 having seed-free surfaces. In the comparative embodiment shown in FIG. 16 to FIG. 18, the seed layers 106′ and the bonding pads 108′ are formed after forming the redistribution layer 112.

For example, referring to FIG. 16, without forming a bonding layer BL1 at an initial step, the redistribution layer 112, the first and second semiconductor dies 114, 116, the underfill structures 120A, 120B, the insulating encapsulant 125 are formed in the same manner over a carrier 102 as described in FIG. 3 to FIG. 6. Thereafter, the structure is flipped and transferred onto a second carrier CX2, and the carrier 102 is debonded to reveal the second surface 112-S2 of the redistribution layer 112.

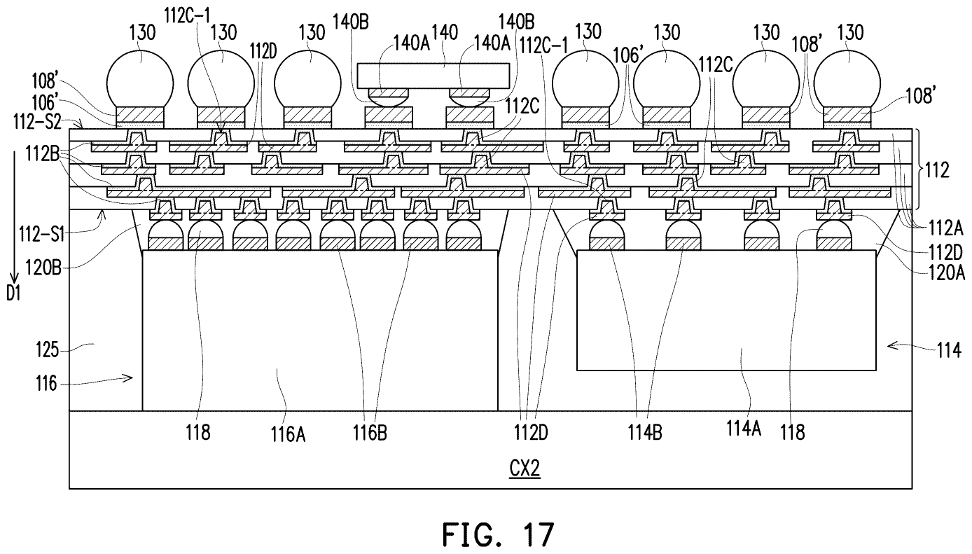

Referring to FIG. 17, in a subsequent step, seed layers 106′ are formed on the second surface 112-S2 of the redistribution layer 112, so that the seed layers 106′ are electrically connected to the seed layers 112B of the redistribution layer 112. Thereafter, bonding pads 108′ are formed over the seed layers 106′. Similar to the method described in FIG. 9, conductive terminals 130 are directly formed on the top surface 108-TS of the bonding pads 108′, and a passive device 140 is directly placed on the top surface 108-TS of the bonding pads 108′.

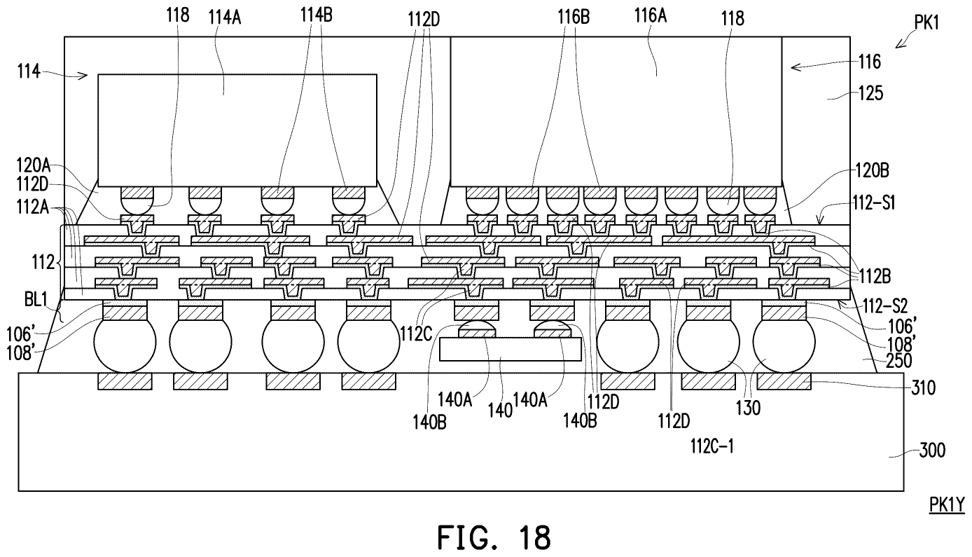

Referring to FIG. 18, after forming the conductive terminals 130 and after placing the passive device 140 on the bonding pads 108′, the second carrier CX2 is debonded, and the resulting package is mounted or attached onto a circuit substrate 300 through the conductive terminals 130. For example, the conductive terminals 130 are physically and electrically connected to the contact pads 310 of the circuit substrate 300. Subsequently, an underfill structure 250 is formed to surround the conductive terminals 130, the seed layers 106′ and the bonding pads 108′. After forming the underfill structure 250, a package structure PK1Y in accordance with some comparative embodiments of the present disclosure is accomplished.

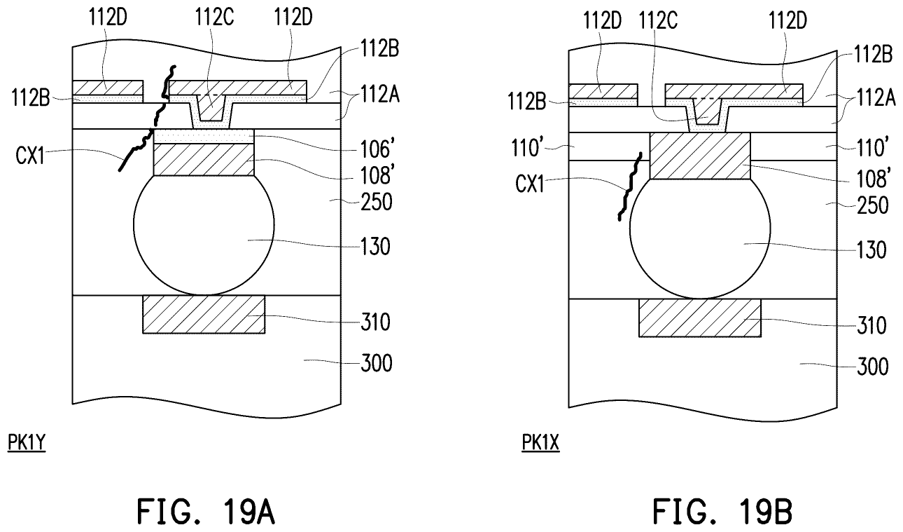

FIG. 19A is an enlarged sectional view of the package structure PK1Y obtained in FIG. 18 according to some comparative embodiments of the disclosure. Referring to FIG. 19A, the seed layers 106′ and the bonding pads 108′ are formed after forming the redistribution layer 112. Therefore, the seed layers 106′ provide a strong adhesion of the bonding pads 108′ to the redistribution layer 112. Under such circumstances, a crack CX1 observed in the underfill structure 250 during a board level reliability test may extend and propagate along the side of the seed layer 106′. This will cause to crack CX1 to extend into the dielectric layers 112A of the redistribution layer 112, and extend towards sidewalls of the seed layers 112B. With the presence of the crack CX1 observed in the dielectric layer 112A, this will cause delamination and result in an opening path that allows for humidity penetration, and results in the formation of RDL dendrite overtime. Therefore, in the package structure PK1Y of the comparative embodiment, as the bonding pads 108′ are formed through a “pad-last” or “UBM-last” process, which requires prior formation of the seed layers 106′ that will induce crack propagation, electrical failure and reliability issues will be observed in the resulting package structure PK1Y due to dielectric delamination and the formation of the RDL dendrite.

FIG. 19B is an enlarged sectional view of the package structure PK1X obtained in FIG. 10 according to some exemplary embodiments of the disclosure. Referring to FIG. 19B, the bonding pads 108 formed on the redistribution layer 112 are formed with seed-free bottom and top surfaces. As such, a crack CX1 observed in the underfill structure 250 during a board level reliability test will stop at the dielectric portion 110′. Due to a weaker adhesion between the bonding pads 108 and the dielectric layer 112A of the redistribution layer 112, the crack CX1 is unlikely to extend into the dielectric layer 112A. Therefore, in the package structure PK1X, and similarly in the package structures PK2X, PK3X, PK4X′ of the embodiments, as the bonding pads 108 are formed through a “pad-first” or “UBM-first” process, the seed layers 106 may be removed through a recessing step. As such, the resulting package structures PK1X, PK2X, PK3X, and PK4X′ will be free of delamination issue, the formation of the RDL dendrite is prevented, and a reliability of the package is improved.

In the above embodiments, without a seed layer formed in between the bonding pads (UBM patterns) of the bonding layer and the dielectric layer of the redistribution layer, a propagation path of a crack into the redistribution layer is removed. Therefore, a cracking issue in the redistribution layer can be prevented in the package structure. Overall, a dielectric delamination issue, and the formation of the RDL dendrite in the redistribution layer is prevented, and the package structure can have improved reliability.

In accordance with some embodiments of the present disclosure, a package structure includes a redistribution layer, a plurality of semiconductor dies and a bonding layer. The redistribution layer has a first surface and a second surface opposite to the first surface, and includes a plurality of conductive lines and a plurality of conductive vias connected to the plurality of conductive lines. Seed layers are located below the conductive lines and the conductive vias, wherein a portion of the seed layers is revealed at the second surface. The semiconductor dies are disposed on the first surface of the redistribution layer and electrically connected to the redistribution layer. The bonding layer is disposed on the second surface of the redistribution layer, wherein the bonding layer comprises a plurality of bonding pads, and a bottom surface of the plurality of bonding pads is directly joined to the portion of the seed layers revealed at the second surface.

In accordance with some other embodiments of the present disclosure, a package structure includes a circuit substrate, a plurality of conductive terminals, a plurality of bonding pads, a redistribution layer and an underfill structure. The conductive terminals are disposed on and electrically connected to the circuit substrate. The bonding pads are joined with the conductive terminals, wherein each of the bonding pads comprises a bottom surface and a top surface, and the top surface is directly joined with the conductive terminals. The redistribution layer is disposed on and electrically connected to the bonding pads, wherein a seed layer of the redistribution layer is directly joined with the bottom surface of the bonding pads. The underfill structure is disposed in between the circuit substrate and the redistribution layer, and laterally surrounding and contacting the conductive terminals and the bonding pads.

In accordance with yet another embodiment of the present disclosure, a method of fabricating a package structure is described. The method includes the following steps: forming a bonding layer, wherein forming the bonding layer comprises forming a plurality of bonding pads on a carrier; forming a redistribution layer on the bonding layer, wherein the redistribution layer is formed with a first surface and a second surface opposite to the first surface. Forming the redistribution layer comprises: forming seed layers; forming a plurality of conductive lines and a plurality of conductive vias connected to the plurality of conductive line, wherein the seed layers is formed below the plurality of conductive lines and the plurality of conductive vias, and a portion of the seed layers is revealed at the second surface of the redistribution layer, and wherein after forming the redistribution layer the bonding layer is disposed on the second surface of the redistribution layer, and a bottom surface of the plurality of bonding pads is directly joined to the portion of the seed layers revealed at the second surface. The method further comprises: disposing a plurality of semiconductor dies on the first surface of the redistribution layer and electrically connecting the plurality of semiconductor dies to the redistribution layer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A package structure, comprising:
a redistribution layer having a first surface and a second surface opposite to the first surface, wherein the redistribution layer comprises:
a plurality of conductive lines and a plurality of conductive vias connected to the plurality of conductive lines;
seed layers located below the plurality of conductive lines and the plurality of conductive vias, wherein a portion of the seed layers is revealed at the second surface;
a plurality of semiconductor dies disposed on the first surface of the redistribution layer and electrically connected to the redistribution layer; and
a bonding layer disposed on the second surface of the redistribution layer, wherein the bonding layer comprises a plurality of bonding pads, and a bottom surface of the plurality of bonding pads is joined to the portion of the seed layers revealed at the second surface.

2. The package structure according to claim 1, wherein each of the plurality of conductive vias comprises a first side and a second side opposite to the first side, wherein the first side is joined with the seed layers, the second side is joined with the plurality of conductive lines, a lateral dimension of each of the plurality of conductive vias increases from the first side to the second side, and the plurality of bonding pads is disposed on the seed layers located over the first side of the plurality of conductive vias.

3. The package structure according to claim 1, wherein the bonding layer further comprises a dielectric portion partially covering sidewalls of the plurality of bonding pads.

4. The package structure according to claim 3, wherein a thickness of the dielectric portion is smaller than a thickness of the plurality of bonding pads, and a bottom surface of the dielectric portion is aligned with the bottom surface of the plurality of bonding pads.

5. The package structure according to claim 1, further comprising:
a plurality of conductive bumps electrically joining the plurality of semiconductor dies to the redistribution layer;
an underfill structure covering the plurality of conductive bumps; and
an insulating encapsulant encapsulating the plurality of semiconductor dies, the plurality of conductive bumps and the underfill structure.

6. The package structure according to claim 1, further comprising a plurality of conductive terminals directly disposed on a top surface of the plurality of bonding pads.

7. The package structure according to claim 1, further comprising a passive device directly disposed on a top surface of the plurality of bonding pads.

8. A package structure, comprising:
a circuit substrate;
a plurality of conductive terminals disposed on and electrically connected to the circuit substrate;
a plurality of bonding pads joined with the plurality of conductive terminals, wherein each of the plurality of bonding pads comprises a bottom surface and a top surface, and the top surface is directly joined with the plurality of conductive terminals;
a redistribution layer disposed on and electrically connected to the plurality of bonding pads, wherein a seed layer of the redistribution layer is directly joined with the bottom surface of the plurality of bonding pads; and
an underfill structure disposed in between the circuit substrate and the redistribution layer, and laterally surrounding and contacting the plurality of conductive terminals and the plurality of bonding pads.

9. The package structure according to claim 8, wherein a surface area of the bottom surface of the plurality of bonding pads contacting the seed layer of the redistribution layer is less than a surface area of the bottom surface of the plurality of bonding pads contacting a dielectric layer of the redistribution layer.

10. The package structure according to claim 8, wherein the redistribution layer comprises a plurality of conductive lines and a plurality of conductive vias joined with the plurality of conductive lines, wherein the plurality of bonding pads is physically separated from the plurality of conductive vias and the plurality of conductive lines of the redistribution layer.

11. The package structure according to claim 8, further comprising a dielectric portion laterally surrounding the plurality of bonding pads, wherein the dielectric portion is recessed from the top surface of the plurality of bonding pads.

12. The package structure according to claim 11, wherein the underfill structure is further surrounding and contacting the dielectric portion.

13. The package structure according to claim 8, further comprising:
a semiconductor die disposed on and electrically connected to the redistribution layer; and
an insulating encapsulant disposed on the redistribution layer and encapsulating the semiconductor die.

14. The package structure according to claim 13, further comprising a plurality of through insulator vias embedded in the insulating encapsulant and electrically connected to the redistribution layer.

15. A method of fabricating a package structure, comprising:
forming a bonding layer, wherein forming the bonding layer comprises forming a plurality of bonding pads on a carrier;
forming a redistribution layer on the bonding layer, wherein the redistribution layer is formed with a first surface and a second surface opposite to the first surface, and forming the redistribution layer comprises:
forming seed layers;
forming a plurality of conductive lines and a plurality of conductive vias connected to the plurality of conductive line, wherein the seed layers is formed below the plurality of conductive lines and the plurality of conductive vias, and a portion of the seed layers is revealed at the second surface of the redistribution layer, and
wherein after forming the redistribution layer, the bonding layer is disposed on the second surface of the redistribution layer, and a bottom surface of the plurality of bonding pads is joined to the portion of the seed layers revealed at the second surface;
disposing a plurality of semiconductor dies on the first surface of the redistribution layer and electrically connecting the plurality of semiconductor dies to the redistribution layer.

16. The method according to claim 15, further comprises:
forming sacrificial seed layers on the carrier prior to forming the plurality of bonding pads;
forming the plurality of bonding pads over the sacrificial seed layers; and
forming a dielectric portion surrounding the sacrificial seed layers and the plurality of bonding pads.

17. The method according to claim 16, further comprises:
debonding the carrier to reveal the sacrificial seed layers; and
performing a recessing step for removing the sacrificial seed layers to reveal a top surface of the plurality of bonding pads, and for partially removing the dielectric portion.

18. The method according to claim 17, wherein after the recessing step, a thickness of the dielectric portion is smaller than a thickness of the plurality of bonding pads, and a bottom surface of the dielectric portion is aligned with the bottom surface of the plurality of bonding pads.

19. The method according to claim 17, wherein after the recessing step, the method further comprises forming a plurality of conductive terminals directly on a top surface of the plurality of bonding pads.

20. The method according to claim 15, further comprises:
forming a plurality of conductive bumps electrically joining the plurality of semiconductor dies to the redistribution layer;
forming an underfill structure covering the plurality of conductive bumps; and
forming an insulating encapsulant encapsulating the plurality of semiconductor dies, the plurality of conductive bumps and the underfill structure.
